(19) United States
(12) Patent Application Publication
(10) Pub. No.: US 2017/0018525 A1
(43) Pub. Date: Jan. 19, 2017

(54) METHOD AND PROCESS FOR EMIB CHIP INTERCONNECTIONS

(71) Applicant: INTEL CORPORATION, Santa Clara, CA (US)

(72) Inventors: Rajendra C. Dias, Phoenix, AZ (US); Manish Dubey, Chandler, AZ (US); Emre Armagan, Tempe, AZ (US)

(21) Appl. No.: 15/121,295

(22) PCT Filed: Mar. 28, 2014
(86) PCT No.: PCT/US2014/032136

§ 371 Date: Aug. 24, 2016

(51) Int. Cl. H01L 23/00

(52) U.S. Cl. CPC H01L 24/81; H01L 24/03; H01L 24/742; H01L 24/16; H01L 2224/0214; H01L 2224/0333; H01L 2924/40102; H01L 2224/0312; H01L 2224/81193; H01L 2224/81815; H01L 2224/81203; H01L 2224/742; H01L 2224/16227; H01L 2224/16057; H01L 2224/16013

(57) ABSTRACT

A method for attaching an integrated circuit (IC) to an IC package substrate includes forming a solder bump on a bond pad of an IC die, forming a solder-wetting protrusion on a bond pad of an IC package substrate, and bonding the solder bump of the IC die to the solder-wetting protrusion of the IC package substrate.

### TECHNICAL FIELD

Embodiments pertain to packaging of integrated circuits. Some embodiments relate to solder bonds for packaged integrated circuits.

### BACKGROUND

Electronic devices often include integrated circuits (ICs) that are connected to a subassembly such as a substrate or motherboard. The ICs can be inserted into an IC package to form a first level assembly before it is incorporated into a higher level assembly. The first level assembly can includes first level interconnect (FLI) that provides electronic continuity from contact pads of one or more IC die to contact pads of the IC package.

As electronic system designs become more complex, it is a challenge to meet the desired size constraints of electronic devices. Some manufactures include FLI in IC packages that have a finer pitch than IC die being packaged. As the feature spacing is reduced, the current methods used to attach IC die to IC packages becomes more challenging and includes increased risk. This can result in low yield of the packaging process. Thus, there are general needs for devices, systems and methods that address the spacing challenges for packaging of ICs yet provide a robust and cost effective design.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, the various examples discussed in the present document.

FIG. 1 illustrates a simplified example of IC attachment to an IC package substrate;

FIG. 2 illustrates another example of IC attachment to an IC package substrate;

FIG. 3 shows a diagram of an example of a method for IC attachment to an IC package substrate in accordance with some embodiments;

FIG. 4 illustrates still another example of IC attachment to an IC package substrate in accordance with some embodiments;

FIG. 5 illustrates still another example of IC attachment to an IC package substrate in accordance with some embodiments;

FIG. 6 shows a simplified illustration of ICs and an IC package substrate in accordance with some embodiments;

FIG. 7 illustrates portions of an example of an automatic laser direct deposition station in accordance with some embodiments;

FIG. 8 is a block diagram of an example of an electronic device incorporating at least one IC attachment and/or method in accordance with at least one embodiment.

### DETAILED DESCRIPTION

A conventional approach to attaching ICs to die packaging includes forming solder balls or bumps on the IC die (Solder on Die or SoD) and then bonding the solder balls to bond pads of a substrate of the IC package. Problems can occur as feature size of the IC package substrate becomes finer to accommodate denser packaging. For instance, multiple IC dice may be included in a single IC package, such as a processor IC and a memory IC. The feature size of FLI between the die may need to be smaller than the feature size of the individual IC die. The mismatch in feature size may lead to bridging between solder bumps.

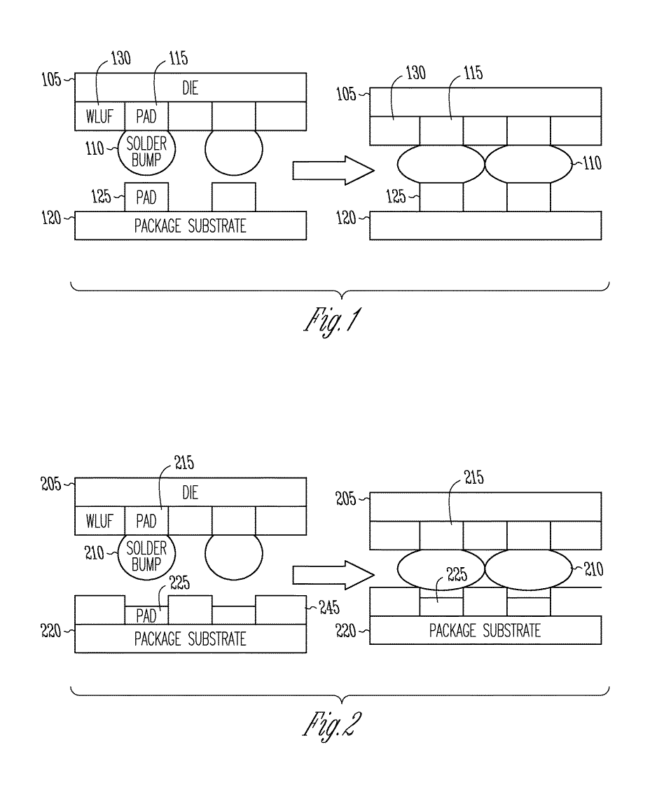

FIG. 1 illustrates a simplified example of IC attachment to an IC package substrate. An IC die 105 with solder bumps 110 attached to the IC bond pads 115 is being bonded to an IC package substrate 120 with substrate bond pads 125. The IC die 105 is shown with wafer level under fill (WLUF 130) around the IC bond pads 115. The solder bumps are heated to facilitate bonding. As the die is moved toward the IC package substrate as part of a chip attach process, the solder bumps 110 can come in contact to form an unintended electrical short between one or both of neighboring IC bond pads 115 and neighboring substrate bond pads 125.

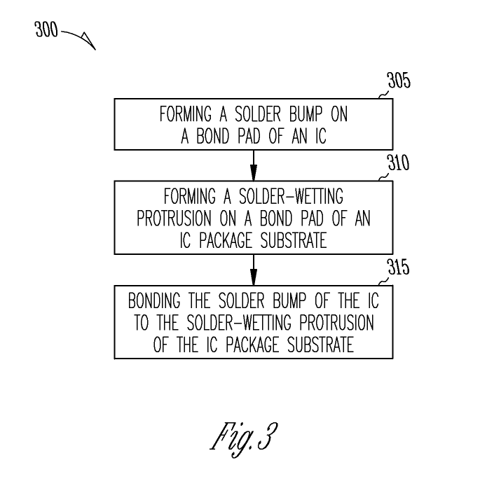

FIG. 2 illustrates another example of IC attachment to an IC package substrate. In this example, the IC package substrate 220 includes substrate bond pads 225 that are defined using a solder mask 245 (i.e., solder mask defined or SMD). The Figure illustrates that, during the bonding process, molten solder bumps can still flatten and once again can come in contact to form an unintended electrical short. An approach to avoiding the bridging between solder bumps is to allow molten solder bumps to make contact and wet a material placed on the package substrate bond pads.

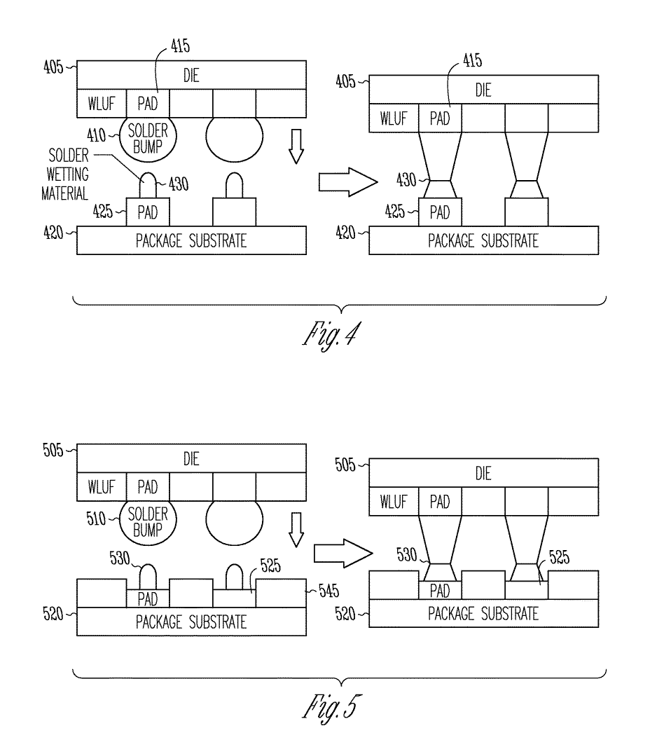

FIG. 3 shows a diagram of an example of a method 300 for IC attachment to an IC package substrate. At 305, a solder bump is formed on a bond pad of an IC die. The solder bump may be a SoD solder ball, a ball grid array or BGA contact, or a controlled collapse chip connection (C4) solder bump for example. The solder bumps may be added at an automatic solder bumping station. The solder bumps may be added using a solder mask placed over one or more IC die and applying solder to the solder mask to form the solder bumps. At 310, a solder-wetting protrusion is formed on a bond pad of an IC package substrate.

FIG. 4 shows an example of a bond pad with a solder-wetting protrusion. An IC die 405 and an IC package substrate 420 are shown in the Figure. The IC package substrate includes a number of substrate bond pads 425, and the bond pads include a surface for electrical connection to the IC die 405. The IC die 405 may include one or more of a processor and a memory. Only two bond pads are shown in the Figure for simplicity. The two substrate bond pads 425 shown in the example include a protrusion 430 of solder-wetting material. Solder-wetting refers to molten solder attaching to the bond pads of the IC and the IC package substrate. The solder-wetting material may include at least one of tungsten, gold, copper, or silver or an alloy including at least one of tungsten, gold, copper, or silver. In certain examples, the solder-wetting material includes solder paste.

In the example of FIG. 4, the solder is located on the IC bond pads 415 of the IC die. The IC bond pads 415 can be heated to provide molten solder. The substrate bond pads 425 may also be heated during solder-wetting. The protrusions 430 of solder-wetting material extend away from the surface of the substrate bond pads 425. The protrusions 430 shown in the example have a bullet-like shape, but the protrusions 430 may have other shapes, such as a cone-like shape or a substantial cone-like shape. A solder-wetting protrusion having a substantial cone-like shape may include a base and an apex, and the width of the base may be greater than the width of the apex. Such a solder-wetting protrusion 430 may have a base with a width of one hundred micrometers (100 microns) or less. In other examples, the solder-wetting protrusion may be a bump or stud. The width of the solder-wetting protrusion is typically less than a width of the surface of the bond pad of the IC package substrate.

Returning to FIG. 3 at 315, the solder bump of the IC die is bonded to the solder-wetting protrusion of the IC package substrate. An example illustration of the bonding is shown on the right in FIG. 4. The solder bump 410 of the IC die can be heated to form a molten solder bump. The solder bump 410 of the IC die is bonded to the solder-wetting protrusion by contacting the molten solder bump with the solder-wetting protrusion. When the molten solder of the solder bump 410 comes into contact with a protrusion of solder-wetting material, the molten solder may wick toward the substrate bond pad and may change shape. The solder bumps 410 wet to the material on the substrate bond pad 425 before solder bridging occurs. This bonding between the IC and the IC package substrate can be accomplished using an automatic IC bonding station. In some examples, the molten solder bump of the IC die is pressed to the solder-wetting protrusion of the IC package substrate as part of the bonding process. This type of bonding can be implemented using an automatic thermal compressive bonding (TCB) station that bonds the IC die to the IC package substrate. Because of the contact of the solder bump 410 with the protrusion of solder-wetting material, formation of solder bridges between flattened solder bumps can be prevented during the pressing.

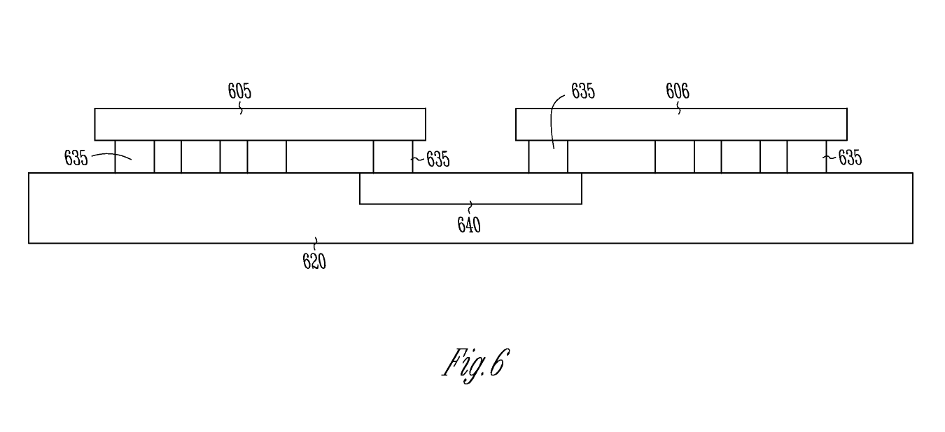

FIG. 5 illustrates another example of IC attachment to an IC package substrate. In this example, the IC package substrate package 520 includes substrate bond pads 525 that are solder mask defined (SMD). As shown in the example of the FIG. 5, the solder bumps 510 again wet to the protrusion 530 on the substrate bond pad 525 before solder bridging occurs.

Although only one IC die is shown in the examples of FIGS. 4 and 5, multiple IC dice may be included in a single IC package, such as a processor IC and a memory IC. It may be desired for the feature size of FLI between the die to be smaller than the feature size of the individual IC die to achieve the required interconnect.

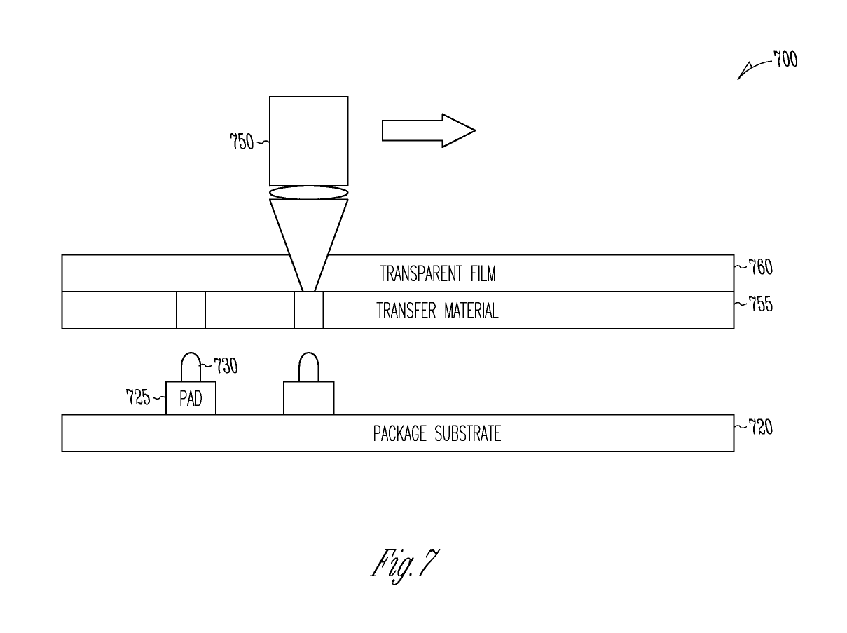

FIG. 6 illustrates an example of ICs and an IC package substrate. Two ICs (605, 606) are included in one IC package having an IC package substrate 620. The example shows a number of interconnections 635 between bond pads of the ICs and bond pads of the IC package substrate 620. The example also shows an embedded interconnect bridge 640 (EmIB) for interconnection between the two ICs. The IC 605 may include a processor (e.g., central processor unit or CPU) having one hundred micrometer (100 μm) die interconnection pitch. The IC package substrate 620 may have 65 μm features (e.g., one or both of FLI and EmIB) to accommodate connection to the second IC 606 within the IC package. Solder-wetting using one or more protrusions on bond pads of the IC package substrate may avoid bridging between solder bumps despite the mismatch in feature size.

Different approaches can be used to form the solder-wetting protrusions described previously herein. According to some examples, a solder-wetting protrusion can be formed on a bond pad by laser direct deposition of the solder-wetting protrusion onto the bond pad.

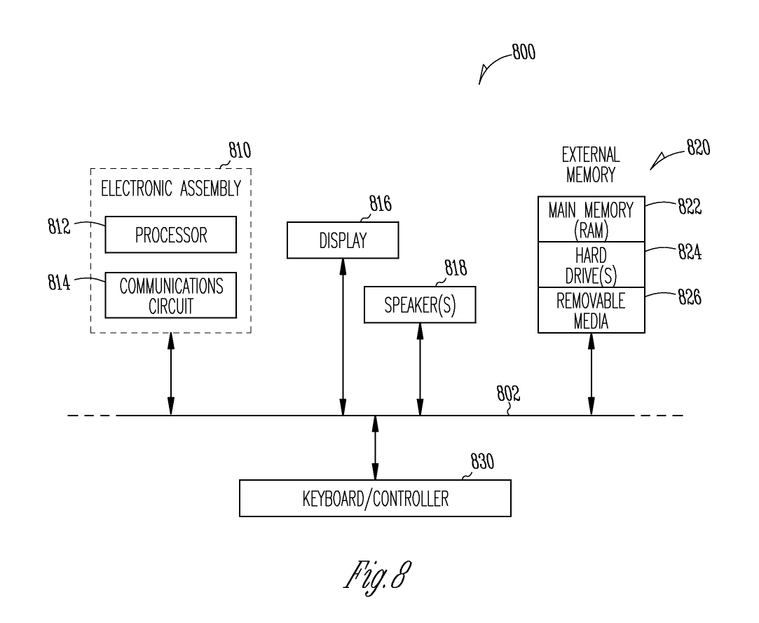

FIG. 7 illustrates portions of an example of an automatic laser direct deposition station 700. The deposition station includes a laser energy source 750 and a platform to hold a work piece. The laser energy source 750 can provide an ultraviolet (UV) laser beam. The laser energy can be provided as a laser pulse. The work piece may include one or more IC package substrates 720 that include bond pads 725. The laser direct deposition station includes a fixture to hold a film of solder-wetting material 755 opposite the bond pads. Laser energy is applied to the film of solder-wetting material 755 to transfer the solder-wetting material to the bond pad of the IC package substrate 720.

In the example shown in FIG. 7, the film of solder-wetting material 755 includes a transparent material (e.g., a substrate of glass or transparent plastic) on one side and the solder-wetting material on the other side. The laser energy is applied to the transparent side of the film. The laser energy source 750 applies laser energy of specified size and duration to irradiate the solder-wetting material through the transparent material. In the example shown, the laser beam is shown as travelling straight from the laser energy source 750 to the film and the bond pad. However, the laser beam may be deflected (e.g., by a lens or mirror) between the laser energy source and the film.

Rapid vaporization at the interface of the transparent material and the solder-wetting material causes the solder-wetting material to be propelled onto a bond pad. Solder flux can be applied to the bond pad of the IC package substrate prior to laser deposition of the solder-wetting protrusion. The addition of solder flux can improve adhesion of the wetting material to the bond pad. The spatial size of the transfer material can be as small as the laser spot size and the spatial size can be of the order of tens of microns. The spatial size can also be determined by the thickness of the transfer material on the film and by the distance of the film from the bond pads. Some advantages of laser direct deposition process in forming the protrusions is that the process is mask-less and has the capability to be implemented using a variety of material. The laser energy can also be used to melt or reflow the material on the package substrate bond pads as well.

The laser energy source can be movable relative to the work piece or the work piece can be moveable relative to the laser energy source. In some examples, the laser energy source 750 is scannable to positions on the film of solder-wetting material 755 opposite the bond pads 725. Pulses of laser energy can be applied to the film of solder-wetting material to transfer the solder-wetting material to the plurality of bond pads. In certain examples, both the laser energy source and the work piece are substantially stationary and the laser energy is scanned over the film of solder-wetting material by controlling a lens or mirror to direct the laser energy to positions on the film to transfer the solder-wetting material. In certain examples, the laser energy is raster scanned (e.g., by a galvo mechanism) over the film at a fast speed. For raster scanning of the laser energy, several thousand points or positions may be scanned per second.

In some examples, the work piece can be moveable relative to the laser energy source. The platform may scan the film of solder-wetting material and the one or more IC package substrates passed the laser energy source. The pulses of laser energy are applied to the film of transparent material to transfer the solder-wetting material onto a bond pad when it is positioned opposite the laser energy source. This approach of moving the work piece relative to the laser energy source is typically slower than the raster scan approach.

Other methods can be used to form the protrusions of solder-wetting material on band pads. According to some examples, a solder-wetting protrusion can be formed on a bond pad of the IC package substrate by laser direct writing of the solder-wetting protrusion onto the bond pad. Direct laser writing or three-dimensional (3D) laser lithography refers to scanning arbitrary 3D structures using photosensitive material. In other examples, a solder-wetting protrusion can include solder paste and the protrusion can be formed on a bond pad by solder paste printing. In certain examples, a solder-wetting protrusion can include a metal, and the protrusion can be plated onto the bond pad, such as by an IC masking and metal deposition process. Other methods of forming the protrusion on the bond pad include wire-stud bonding solder-wetting material to the bonding pad, attaching a solder-wetting micro-ball to the bond pad, attaching a solder-wetting microdot to the bond pad, solder jetting the solder-wetting material onto the bond pad, and injection molding the solder-wetting material onto the bond pad.

An example of an electronic device using semiconductor chip assemblies and solder-wetting protrusion as described in the present disclosure is included to show an example of a higher level device application. FIG. 8 is a block diagram of an example of an electronic device 800 incorporating at least one solder and/or method in accordance with at least one embodiment. Electronic device 800 is merely one example of an electronic system in which embodiments can be used. Examples of electronic devices 800 include, but are not limited to personal computers, tablet computers, mobile telephones, game devices, MP3 or other digital music players, etc. In this example, electronic device 800 comprises a data processing system that includes a system bus 802 to couple the various components of the system. System bus 802 provides communications links among the various components of the electronic device 800 and can be implemented as a single bus, as a combination of busses, or in any other suitable manner.

An electronic assembly 810 is coupled to system bus 802. The electronic assembly 810 can include any circuit or combination of circuits. In one embodiment, the electronic assembly 810 includes a processor 812 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 810 are a custom circuit, an application-specific integrated circuit (ASIC), or the like, such as, for example, one or more circuits (such as a communications circuit 814) for use in wireless devices like mobile telephones, personal data assistants, portable computers, two-way radios, and similar electronic systems. The IC can perform any other type of function.

The electronic device 800 can also include an external memory 820, which in turn can include one or more memory elements suitable to the particular application, such as a main memory 822 in the form of random access memory (RAM), one or more hard drives 824, and/or one or more drives that handle removable media 826 such as compact disks (CD), flash memory cards, digital video disk (DVD), and the like.

The electronic device 800 can also include a display device 816, one or more speakers 818, and a keyboard and/or controller 830, which can include a mouse, trackball, touch screen, voice-recognition device, or any other device that permits a system user to input information into and receive information from the electronic device 800.

Demand for smaller electronic device size together with demand for increased device functionality creates challenges for IC packaging. As explained previously, problems can occur as feature size of the IC packages becomes finer to accommodate denser packaging. For instance, the feature size of FLI between the die may need to be smaller than the feature size of the individual IC die. The mismatch in feature size may lead to bridging between solder bumps. Solder-wetting using one or more protrusions of solder-wetting material on bond pads of the IC package substrate may avoid bridging between solder bumps despite the mismatch in feature size.

### Additional Notes and Examples

To better illustrate the methods and apparatuses disclosed herein, a non-limiting list of examples is provided below.

Example 1 can include subject matter (such as a method, means for performing acts, or a machine readable medium that can cause the machine to perform acts) including forming a solder bump on a bond pad of an IC die, forming a solder-wetting protrusion on a bond pad of an IC package substrate, and bonding the solder bump of the IC die to the solder-wetting protrusion of the IC package substrate.

In Example 2, the subject matter of Example 1 optionally includes forming a solder-wetting protrusion on the bond pad of the IC package substrate includes laser direct deposition of the solder-wetting protrusion onto the bond pad of the IC package substrate.

In Example 3, the subject matter of Example 2 optionally includes arranging a film of solder-wetting material opposite the bond pad of the IC package substrate, and applying laser energy to the film of solder-wetting material to transfer the solder-wetting material to the bond pad of the IC package substrate.

In Example 4, the subject matter of example 2 optionally includes arranging, opposite the bond pad of the IC package substrate, a film having the solder-wetting material on one side and a transparent material on the other side, and applying laser energy to the transparent side of the film.

In Example 5, the subject matter of one or any combination of Examples 3 and 4 optionally includes arranging the film of solder-wetting material opposite a plurality of bond pads of one or more IC package substrates, and scanning a laser energy source to positions on the film of solder-wetting material opposite the plurality of bond pads and applying pulses of laser energy to the film of solder-wetting material to transfer the solder-wetting material to the plurality of bond pads.

In Example 6, the subject matter of one or any combination of Examples 3 and 4 optionally includes arranging the film of solder-wetting material opposite a plurality of bond pads of one or more IC package substrates, and scanning the plurality of bonds passed the laser energy source and applying a pulses of laser energy to the film of transparent material to transfer the solder-wetting material onto a bond pad when it is positioned opposite the laser energy source.

In Example 7, the subject matter of one or any combination of Examples 2-6 optionally includes applying solder flux to the bond pad of the IC package substrate prior to laser deposition of the solder-wetting protrusion.

In Example 8, the subject matter of one or any combination of Examples 1-7 optionally includes laser direct writing of the solder-wetting protrusion onto the bond pad of the IC package substrate.

In Example 9, the subject matter of one or any combination of Examples 1-8 optionally includes at least one of wire-stud bonding solder-wetting material to the bonding pad, attaching a solder-wetting micro-ball to the bond pad, attaching a solder-wetting microdot to the bond pad, solder jetting the solder-wetting material onto the bond pad, or injection molding the solder-wetting material onto the bond pad.

In Example 10, the subject matter of one or any combination of Examples 1-9 optionally includes at least one of solder paste printing the solder-wetting protrusion on the bond pad or plating the solder-wetting protrusion on the bond pad.

In Example 11, the subject matter of one or any combination of Examples 1-10 optionally includes heating the solder bump to form a molten solder bump and contacting the molten solder bump with the solder-wetting protrusion.

In Example 12, the subject matter of one or any combination of Examples 1-11 optionally includes heating the solder bump to form a molten solder bump and pressing the molten solder bump of the IC die to the solder-wetting protrusion of the IC package substrate.

Example 13 can include subject matter, or can optionally be combined with one or any combination of Examples 1-12 to include subject matter (such as an apparatus), including means for forming a solder bump on a bond pad of an integrated circuit (IC) die, means for forming a solder-wetting protrusion on a bond pad of an IC package substrate, and means for bonding the solder bump of the IC die to the solder-wetting protrusion of the IC package substrate.

In Example 14, the means for forming a solder-wetting protrusion on the bond pad of Example 13 optionally includes an automatic laser direct deposition station.

In Example 15, the subject matter of Example 14 optionally includes a film of solder-wetting material on a transparent substrate and arranged opposite the bond pad of the IC package substrate, and a laser energy source to apply laser energy to the transparent substrate to transfer the solder-wetting material onto the bond pad of the IC package substrate.

In Example 16, the subject matter of one or any combination of Examples 14-15 optionally includes a film of solder-wetting material arranged opposite a plurality of bond pads of one or more IC package substrates, and the applied laser energy is optionally scannable to positions on the film of transfer material opposite the plurality of bond pads.

In Example 17, the subject matter of one or any combination of Examples 14-15 optionally includes film of solder-wetting material is arranged opposite a plurality of bond pads of one or more IC package substrates, wherein the film of solder-wetting material and the one or more IC package substrates are movable relative to the laser energy source to position a bond pad and solder-wetting material opposite the applied laser energy.

In Example 18, the means for bonding the solder bump of the IC die to the solder-wetting protrusion of the IC package substrate of any one of Examples 13-17 optionally includes an automatic thermal compressive bonding (TCB) station configured to bond the IC die to the IC package substrate.

Example 19 can include subject matter, or can optionally be combined with one or any combination of Examples 1-18 to include subject matter (such as an electronic assembly including an integrated circuit (IC) package substrate, a number of bond pads on the IC package substrate, wherein a bond pad includes a surface for electrical connection to an IC die, and one or more protrusions of solder-wetting material extending away from the surface of one or more of the number of bond pads.

In Example 20 the subject matter of Example 19 can optionally include a solder-wetting protrusion that includes a base and an apex, wherein a width of the base is greater than a width of the apex.

In Example 21, the subject matter of claim 20 can optionally include a solder-wetting protrusion having a base width of one hundred micrometers (100 microns) or less.

In Example 22, the subject matter of one or any combination of Examples 19-21 optionally includes a solder-wetting protrusion having a width less than a width of the surface of the bond pad of the IC package substrate.

In Example 23, the subject matter of one or any combination of Examples 19-22 optionally includes a solder-wetting protrusion that includes at least one of tungsten, gold, copper, or silver.

In Example 24, the subject matter of one or any combination of Examples 19-23 optionally includes a solder-wetting protrusion that includes solder paste.

In Example 25, the subject matter of one or any combination of Examples 19-23 optionally includes the IC die bonded to the IC package substrate, wherein the IC die includes at least one of a processor and a memory.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the disclosure can be practiced. These embodiments are also referred to herein as “examples.” In the event of inconsistent usages between this document and any documents incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code can form portions of computer program products. Further, the code can be tangibly stored on one or more volatile or non-volatile computer-readable media during execution or at other times. These computer-readable media can include, but are not limited to, hard disks, removable magnetic disks, removable optical disks (e.g., compact disks and digital video disks), magnetic cassettes, memory cards or sticks, random access memories (RAM's), read only memories (ROM's), and the like. In some examples, a carrier medium can carry code implementing the methods. The term “carrier medium” can be used to represent carrier waves on which code is transmitted.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

1-25. (canceled)

26. A method for attaching an integrated circuit (IC) to an IC package substrate, the method comprising:
forming a solder bump on a bond pad of an IC die;
forming a solder-wetting protrusion on a bond pad of an IC package substrate; and
bonding the solder bump of the IC die to the solder-wetting protrusion of the IC package substrate.

27. The method of claim 26, wherein forming a solder-wetting protrusion on the bond pad of the IC package substrate includes laser direct deposition of the solder-wetting protrusion onto the bond pad of the IC package substrate.

28. The method of claim 27, wherein laser direct deposition of the solder-wetting protrusion includes:
arranging a film of solder-wetting material opposite the bond pad of the IC package substrate; and
applying laser energy to the film of solder-wetting material to transfer the solder-wetting material to the bond pad of the IC package substrate.

29. The method of claim 27, wherein laser direct deposition of the solder-wetting protrusion includes:
arranging, opposite the bond pad of the IC package substrate, a film having solder-wetting material on one side and a transparent material on the other side, and applying laser energy to the transparent side of the film.

30. The method of claim 28, wherein arranging a film of solder-wetting material includes arranging the film of solder-wetting material opposite a plurality of bond pads of one or more IC package substrates, and wherein applying laser energy includes scanning a laser energy source to positions on the film of solder-wetting material opposite the plurality of bond pads and applying pulses of laser energy to the film of solder-wetting material to transfer the solder-wetting material to the plurality of bond pads.

31. The method of claim 28, wherein arranging a film of solder-wetting material includes arranging the film of solder-wetting material opposite a plurality of bond pads of one or more IC package substrates, and wherein applying laser energy includes scanning the plurality of bonds passed the laser energy source and applying a pulses of laser energy to the film of transparent material to transfer the solder-wetting material onto a bond pad when it is positioned opposite the laser energy source.

32. The method of claim 27, including applying solder flux to the bond pad of the IC package substrate prior to laser deposition of the solder-wetting protrusion.

33. The method of claim 26, wherein forming a solder-wetting protrusion on the bond pad of the IC package substrate includes laser direct writing of the solder-wetting protrusion onto the bond pad of the IC package substrate.

34. The method of claim 26, wherein forming a solder-wetting protrusion on the bond pad of the IC package substrate includes one of wire-stud bonding solder-wetting material to the bonding pad, attaching a solder-wetting micro-ball to the bond pad, attaching a solder-wetting microdot to the bond pad, solder jetting the solder-wetting material onto the bond pad, or injection molding the solder-wetting material onto the bond pad.

35. The method of claim 26, wherein forming a solder-wetting protrusion on the bond pad of the IC package substrate includes at least one of solder paste printing the solder-wetting protrusion on the bond pad or plating the solder-wetting protrusion on the bond pad.

36. The method of claim 26, wherein bonding the solder bump of the IC die to the solder-wetting protrusion of the IC package substrate includes heating the solder bump to form a molten solder bump and contacting the molten solder bump with the solder-wetting protrusion.

37. The method of claim 26, wherein bonding the solder bump of the IC die to the solder-wetting protrusion of the IC package substrate includes heating the solder bump to form a molten solder bump and pressing the molten solder bump of the IC die to the solder-wetting protrusion of the IC package substrate.

38. An electronic assembly including:
an integrated circuit (IC) package substrate;
a number of bond pads on the IC package substrate, wherein a bond pad includes a surface for electrical connection to an IC die; and
one or more protrusions of solder-wetting material extending away from the surface of one or more of the number of bond pads.

39. The electronic assembly of claim 38, wherein a solder-wetting protrusion includes a base and an apex, wherein a width of the base is greater than a width of the apex.

40. The electronic assembly of claim 39, wherein the base has a width of one hundred micrometers (100 microns) or less.

41. The electronic assembly of claim 38, wherein a width of a solder-wetting protrusion is less than a width of the surface of the bond pad of the IC package substrate.

42. The electronic assembly of claim 38, including the IC die bonded to the IC package substrate, wherein the IC die includes at least one of a processor and a memory.

43. An apparatus for forming IC interconnections, the apparatus comprising:
a solder bumping station configured to form a solder bump on a bond pad of an integrated circuit (IC) die;
an automatic laser direct deposition station configured to form a solder-wetting protrusion on a bond pad of an IC package substrate; and
an automatic thermal compressive bonding (TCB) station configured to bond the IC die to the IC package substrate configured to bond the solder bump of the IC die to the solder-wetting protrusion of the IC package substrate.

44. The apparatus of claim 43, wherein the laser direct deposition station includes:
a film of solder-wetting material on a transparent substrate and arranged opposite the bond pad of the IC package substrate; and
a laser energy source to apply laser energy to the transparent substrate to transfer the solder-wetting material onto the bond pad of the IC package substrate.

45. The apparatus of claim 44, wherein the film of solder-wetting material is arranged opposite a plurality of bond pads of one or more IC package substrates, and wherein the applied laser energy is scannable to positions on the film of transfer material opposite the plurality of bond pads.
